(19) United States
(12) Patent Application Publication
(10) Pub. No.: US 2010/0078773 A1
(43) Pub. Date: Apr. 1, 2010

(54) Semiconductor device and method of forming semiconductor device

(75) Inventor: Shigeo Ishikawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY. INC., Tokyo (JP)

(21) Appl. No.: 12/585,825

(22) Filed: Sep. 25, 2009

(30) Foreign Application Priority Data
Sep. 29, 2008 (JP) P2008-249652

(51) Int. Cl. H01L 29/06; H01L 21/302

(52) U.S. Cl. 257/635; 438/759; 257/E21.214; 257/E29.005

(57) ABSTRACT

A semiconductor device includes a substrate, a semiconductor device structure over the substrate, an insulating film that covers the semiconductor device structure, and a stress-compensation film over the insulating film. The stress-compensation film has a first stress that compensates a second stress working to bend the substrate.

### BACKGROUND OF THE INVENTION

1. Field of the Invention

The present invention generally relates to a semiconductor device and a method of forming the same. More specifically, a semiconductor device and a manufacturing method of a semiconductor device capable of preventing the bending of a substrate, the bending may be caused when grinding the substrate from the back surface side after forming a semiconductor device on the substrate.

Priority is claimed on Japanese Patent Application No. 2008-249652, filed Sep. 29, 2008, the content of which is incorporated herein by reference.

2. Description of the Related Art

Generally, forming a semiconductor device may include stacking layers over a substrate, wherein the layers have having various stresses. The bending of a substrate may be caused by the stresses of layers stacked over the substrate. In some cases, the substrate bending may be large enough to cause problems with carrying error and large size-variations. The carrying error is caused by a carrier that carries the substrate. The large size-variations are critical for accurate exposure process.

There are methods of solving the problems. According to one method, a bending-controlling layer is formed on the bottom surface of the substrate before the differently stressed layers are stacked over the top surface of the substrate. The bending-controlling layer controls the bending of the substrate while stacking the differently stressed layers over the substrate. The bending-controlling layer is then removed at an optional timing. In other method, the structure of the bending-controlling layer may be optimized to effectively control the amount of bending of the substrate during the processes for forming a semiconductor device.

In recent years, there has been increased the requirement for reducing the thickness of a semiconductor device for the purpose of packaging the semiconductor device at a high density. To satisfy the requirement, it is effective to polish the bottom surface of a substrate after the semiconductor device structure is formed on the top surface of the substrate has been completed. The semiconductor device structure may include, but is not limited to, one or more semiconductor elements that each act or perform particular functions, and one or more interconnection layers that interconnect the elements. Typical examples of the semiconductor elements may include, but is not limited to, transistors and capacitors.

### SUMMARY

In one embodiment, a semiconductor device may include, but is not limited to, a substrate; a semiconductor device structure over the substrate, an insulating film that covers the uppermost level interconnection layer; and a stress-compensation film. The semiconductor device structure includes an uppermost level interconnection layer. The stress-compensation film has a first stress that compensates a second stress, the second stress working to bend the substrate. The second stress is generated by polishing the bottom surface of the substrate, the first stress of the stress-compensation film being greater than a third stress of the insulating film.

In another embodiment, a semiconductor device may include, but is not limited to, a substrate; a semiconductor device structure over the substrate; an insulating film that covers the semiconductor device structure; and a stress-compensation film over the insulating film, the stress-compensation film having a first stress that compensates a second stress, the second stress working to bend the substrate.

In still another embodiment, a method of forming a semiconductor device may include, but is not limited to, the following processes. A semiconductor device structure is formed over the top surface of a substrate. A stress-compensation film is formed over the semiconductor device structure, wherein the stress-compensation film has a first stress. The bottom surface of the substrate is polished while generating a second stress on the substrate, wherein the second stress works to bend the substrate, and the second stress is compensated by the stress-compensation film with the first stress.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a schematic perspective view illustrating a semiconductor device with a polished surface in accordance with a first preferred embodiment of the present invention;

FIG. 1B is a fragmentary cross sectional elevation view illustrating the semiconductor device with the polished surface of FIG. 1A;

FIG. 2A is a schematic cross sectional elevation view illustrating no bending of the unpolished substrate before the polishing process is carried out in accordance with the first preferred embodiment of the present invention;

FIG. 2B is a schematic cross sectional elevation view illustrating the bending of the polished substrate after the polishing process is carried out in accordance with the first preferred embodiment of the present invention;

FIG. 3A is a schematic perspective view illustrating a semiconductor device before an upper multi-layered structure is formed in accordance with the first preferred embodiment of the present invention;

FIG. 3A is a schematic perspective view illustrating a semiconductor device after an upper multi-layered structure has been formed in accordance with the first preferred embodiment of the present invention;

FIG. 4A is a schematic perspective view illustrating a semiconductor device having a thickness-reduced substrate with a polished bottom surface in the related art;

FIG. 4B is a fragmentary enlarged cross sectional elevation view illustrating the semiconductor device of FIG. 4A;

FIG. 5A is a schematic cross sectional elevation view illustrating no bending of the unpolished substrate before the polishing process is carried out; and

FIG. 5B is a schematic cross sectional elevation view illustrating the bending of the polished substrate after the polishing process is carried out.

### DETAILED DESCRIPTION OF THE PREFERRED EMBODIMENTS

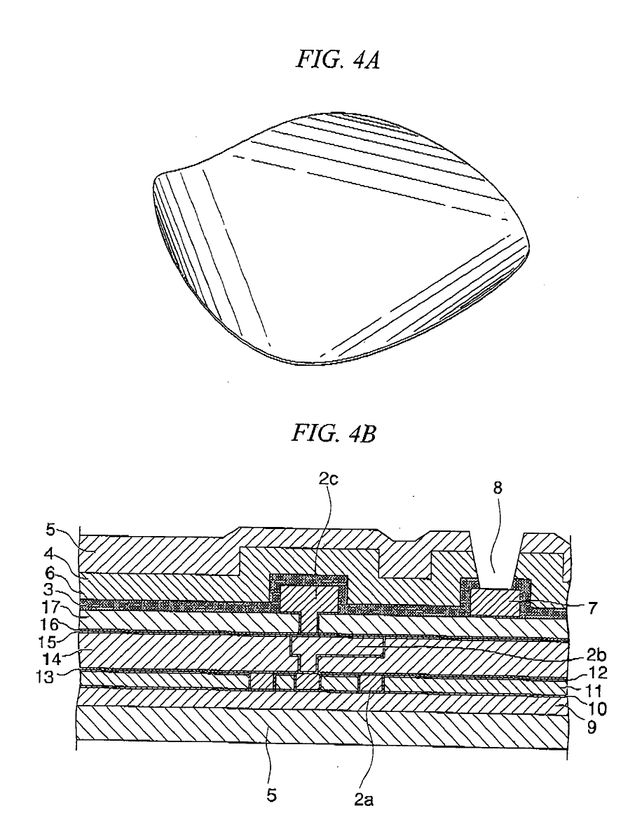

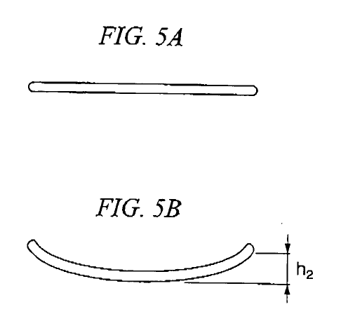

Before describing the present invention, the related art will be explained in detail with reference to FIGS. 4A, 4B, 5A and 5B, in order to facilitate the understanding of the present invention. Polishing the bottom surface of a substrate will be effective to reduce the thickness of a semiconductor device for the purpose of packaging the semiconductor device at a high density. Such polishing process reduces the thickness of the substrate, thereby reducing the mechanical strength of the polished substrate, so that the polished becomes likely to be bent by stress. The substrate once bent makes it difficult to accomplish the dicing process for dicing the substrate into a plurality of chips, so that each chip will then be packaged.

The mechanism of the bending of a thickness-reduced substrate with the polished bottom surface will be described with reference to FIGS. 4A and 4B. FIG. 4A is a schematic perspective view illustrating a semiconductor device having a thickness-reduced substrate with a polished bottom surface in the related art. FIG. 4B is a fragmentary enlarged cross sectional elevation view illustrating the semiconductor device of FIG. 4A.

As shown in FIG. 4B, the semiconductor device may include a substrate 1, a semiconductor device structure over the substrate 1, an insulating layer 3, a passivation film 4 and a protection film 5. The semiconductor device structure may include, but is not limited to, a lower inter-layer insulator 9, Cu-stopper films 10, 13 and 16, cap layers 12 and 15, low dielectric films 11 and 14, first-level interconnection layers 2a of Cu, second-level interconnection layers 2b of Cu, and third-level interconnection layers 2c of Al, a bonding pad 7 under a bonding pad opening 8, and an upper inter-layer insulator 17. The lower inter-layer insulator 9 is provided over the top surface of the substrate 1. A Cu-stopper film 10 is provided over the lower inter-layer insulator 9. The low dielectric film 11 is provided over the Cu-stopper film 10. The first-level interconnection layers 2a of Cu extend over the Cu-stopper film 10. The first-level interconnection layers 2a of Cu are embedded in the low dielectric film 11. The cap layer 12 is provided over the low dielectric film 11. The Cu-stopper film 13 is provided over the first-level interconnection layers 2a of Cu and over the cap layer 12. The low dielectric film 14 is provided over the Cu-stopper film 13. The second-level interconnection layer 2b of Cu is disposed in the low dielectric film 14. The second-level interconnection layer 2b of Cu is electrically connected through a contact plug to the first-level interconnection layers 2a of Cu. The cap layer 15 is provided over the low dielectric film 14. The Cu-stopper film 16 is provided over the second-level interconnection layer 2b of Cu and the low dielectric film 14. The upper inter-layer insulator 17 is provided over the Cu-stopper film 16. The bonding pad 7 is provided over the upper inter-layer insulator 17. The upper multi-layered structure has the bonding pad opening 8 which is positioned over the bonding pad 7. The third-level interconnection layer 2c of Al extends over the upper inter-layer insulator 17. The third-level interconnection layer 2c of Al is electrically connected through a contact plug to the second-level interconnection layer 2b of Cu. The third-level interconnection layer 2c of Al performs as the uppermost-level interconnection layer 2c. The uppermost-level interconnection layer 2c extends over the top surface of the substrate 1. The insulating layer 3 covers the uppermost-level interconnection layer 2c and the upper inter-layer insulator 17. The passivation film 4 covers the insulating layer 3. The protective layer 5 covers the passivation film 4. The substrate 1 has a bottom surface which has been polished after the above-described multi-layer structure had been formed over the top surface of the substrate 1. The polishing process for polishing the bottom surface of the substrate is carried out to reduce the thickness of the substrate 1.

As shown in FIGS. 4A and 4B, the semiconductor device is formed over the top surface of the substrate 1, before the substrate 1 from the back surface side is polished. FIG. 5A is a schematic cross sectional elevation view illustrating no bending of the unpolished substrate before the polishing process is carried out. FIG. 5B is a schematic cross sectional elevation view illustrating the bending of the polished substrate after the polishing process is carried out.

As shown in FIG. 5A, the unpolished substrate 1 has no bending. Namely, the substrate 1 has no bending before the polishing process is carried out and even after the semiconductor device is formed over the top surface of the substrate 1.

As shown in FIG. 5B, the polished substrate 1 has a larger amount “h₂” of bending. Namely, the substrate 1 has the larger amount “h₂” of bending after the bottom surface of the semiconductor substrate 1 is polished. Polishing the bottom surface of the semiconductor substrate 1 allows the tensile stress to be applied to the substrate 1, thereby bending the substrate 1 by itself. The bottom surface of the substrate 1 is expanded but the top surface of the substrate 1 is shrunken. The larger amount “h₂” of the bending of the substrate 1 may be caused when the substrate 1 has a larger stress or when removing a film that is suppressing the substrate 1 from bending.

It is desirable to prevent the substrate from bending when the bottom surface of the substrate is polished after the semiconductor device has been formed over the top surface of the substrate. Dicing the substrate free of any bending is easier than dicing the substrate with some degree of bending. Polishing the substrate reduces the thickness of the substrate. The thickness-reduced substrate allows a high density integration of the semiconductor package.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

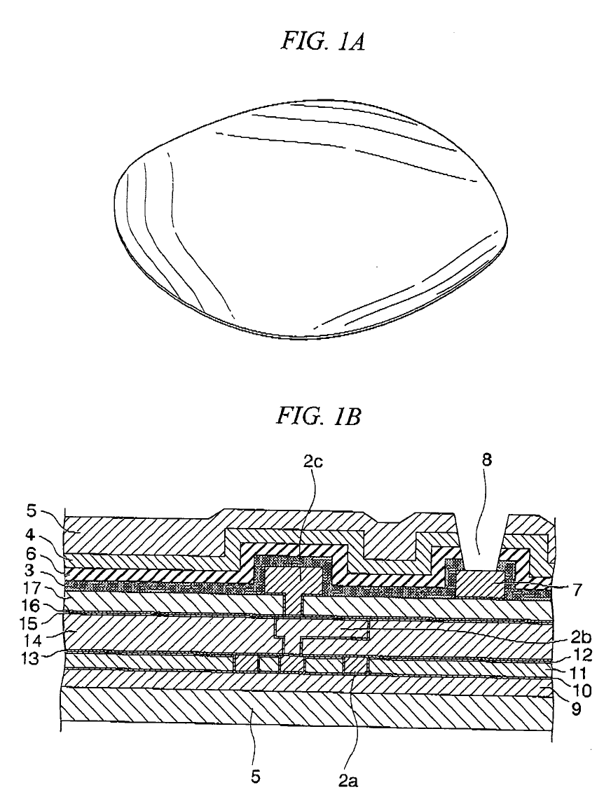

FIG. 1A is a schematic perspective view illustrating a semiconductor device with a polished surface in accordance with a first preferred embodiment of the present invention. FIG. 1B is a fragmentary cross sectional elevation view illustrating the semiconductor device with the polished surface of FIG. 1A.

A semiconductor device includes a substrate, a semiconductor device structure and an upper multi-layered structure. The semiconductor device structure is provided over the top surface of the substrate. The upper multi-layered structure covers the semiconductor device structure. The substrate has the bottom surface that is polished. The semiconductor device structure may include, but is not limited to, transistors, capacitors and interconnection layers. The upper multi-layered structure may include, but is not limited to, a stress-compensation film. In some cases, the upper multi-layered structure may include, but is not limited to, a stress-compensation film, a passivation film and a protective film.

With reference to FIGS. 1A and 1B, a semiconductor device includes a substrate 1, a semiconductor device structure and an upper multi-layered structure. The semiconductor device structure has semiconductor elements which may be, but are not limited to, what are illustrated in FIG. 1B.

In some cases, the semiconductor device structure may include, but is not limited to, a lower inter-layer insulator 9, Cu-stopper films 10, 13 and 16, cap layers 12 and 15, low dielectric films 11 and 14, first-level interconnection layers 2a of Cu, second-level interconnection layers 2b of Cu, and third-level interconnection layers 2c of Al, a bonding pad 7 under a bonding pad opening 8, and an upper inter-layer insulator 17. The lower inter-layer insulator 9 is provided over the top surface of the substrate 1. A Cu-stopper film 10 is provided over the lower inter-layer insulator 9. The low dielectric film 11 is provided over the Cu-stopper film 10. The first-level interconnection layers 2a of Cu extend over the Cu-stopper film 10. The first-level interconnection layers 2a of Cu are embedded in the low dielectric film 11. The cap layer 12 is provided over the low dielectric film 11. The Cu-stopper film 13 is provided over the first-level interconnection layers 2a of Cu and over the cap layer 12. The low dielectric film 14 is provided over the Cu-stopper film 13. The second-level interconnection layer 2b of Cu is disposed in the low dielectric Elm 14. The second-level interconnection layer 2b of Cu is electrically connected through a contact plug to the first-level interconnection layers 2a of Cu. The cap layer 15 is provided over the low dielectric film 14. The Cu-stopper film 16 is provided over the second-level interconnection layer 2b of Cu and the low dielectric film 14. The upper inter-layer insulator 17 is provided over the Cu-stopper film 16. The bonding pad 7 is provided over the upper inter-layer insulator 17. The upper multi-layered structure has the bonding pad opening 8 which is positioned over the bonding pad 7. The third-level interconnection layer 2c of Al extends over the upper inter-layer insulator 17. The third-level interconnection layer 2c of Al is electrically connected through a contact plug to the second-level interconnection layer 2b of Cu. The third-level interconnection layer 2c of Al performs as the uppermost-level interconnection layer 2c.

The upper multi-layered structure may include, but is not limited to, an oxide film 3, a stress-compensation film 6, a passivation film 4, and a protective film 5. The semiconductor device structure including the uppermost-level interconnection layer 2c is provided over the top surface of the substrate 1. The upper multi-layered structure is provided over the upper inter-layer insulator 17 and the semiconductor device structure including the uppermost-level interconnection layer 2c. The oxide film 3 covers the semiconductor device structure including the uppermost-level interconnection layer 2c. The oxide film 3 covers the upper inter-layer insulator 17 and the semiconductor device structure including the uppermost-level interconnection layer 2c. The stress-compensation film 6 covers the oxide film 3. The passivation film 4 covers the stress-compensation film 6. The protective film 5 covers the passivation film 4. The substrate 1 has a reduced thickness. The substrate 1 has the top surface over which the semiconductor device structure is provided. The substrate 1 has the bottom surface that is polished.

As described above, the stress-compensation film 6 may be provided over the oxide film 3 and under the passivation film 4. In other cases, the stress-compensation film 6 may be provided over the passivation film 4 and under the protective film 5.

The absence of stress-compensation film 6 would allow that the substrate 1 is considerably bent due to tensile stress degenerated by polishing the bottom surface of the substrate 1. If the upper multi-layered structure were free of the stress-compensation film 6, it would be difficult to prevent the substrate 1 from being bent due to tensile stress degenerated by polishing the bottom surface of the substrate 1.

The presence of the stress-compensation film 6 prevents the substrate 1 from being considerably bent due to tensile stress degenerated by polishing the bottom surface of the substrate 1. If the upper multi-layered structure includes the stress-compensation film 6, it is possible to prevent the substrate 1 from being considerably bent due to tensile stress degenerated by polishing the bottom surface of the substrate 1.

The stress-compensation film 6 compensates tensile stress that is generated by polishing the bottom surface of the substrate 1, thereby preventing the substrate 1 from being considerably bent due to the tensile stress. The stress-compensation film 6 has a compensatable-stress that the stress-compensation film 6 is able to compensate. The compensatable-stress of the stress-compensation film 6 may be adapted so that the compensatable-stress corresponds to the tensile stress that bends the substrate 1, wherein the tensile stress is generated by polishing the bottom surface of the substrate 1. The stress-compensation film 6 has a compensatable-stress which is a stress that the stress-compensation film 6 is able to compensate. The compensatable-stress of the stress-compensation film 6 may be adapted by selecting the material of the substrate 1 and by adapting the thickness of the substrate 1 as well as selecting the material and dimension of each element of the semiconductor device structure.

The compressive stress of the stress-compensation film 6 compensates the stress that works to bend the substrate 1. A typical example of the stress that works to bend the substrate 1 may be, but is not limited to, a tensile stress. In some cases, the compensatable-stress of the stress-compensation film 6 may be, but is not limited to, in the range of −200 MPa to −350 MPa. The sign (−) means compressive type of stress.

In some cases, the thickness of the stress-compensation film 6 may be, but is not limited to, in the range of 1.0 μm to 2.0 μm. When the thickness of the stress-compensation film 6 is less than the above range, it might be possible that the stress-compensation film 6 of the thin thickness will not be sufficiently enough to compensate the stress that works to bend the substrate 1. When the thickness of the stress-compensation film 6 exceeds the above range, the overall thickness of the semiconductor device is large and it is difficult to realize the desirable high density packaging of the semiconductor device.

In addition, the stress compensation layer may have either a single-layered structure or a multi-layered structure. In the embodiment shown in FIG. 1B, the stress-compensation film 6 has a single-layered structure, wherein the stress-compensation film 6 is a different film from the oxide film 3 and from the passivation film. As a modification to the embodiment shown in FIG. 1B, it is possible that the oxide film may also perform as the stress-compensation film. It is also possible as a modification that that the passivation film may also perform as the stress-compensation film. It is also possible that each of the oxide film and the passivation film may also perform as the stress-compensation film. It is also possible that the stress-compensation film that dedicates to compensate the stress, in addition to the oxide film that may also perform as the additional stress-compensation film, wherein the stress-compensation multi-layered structure is provided. It is also possible that the stress-compensation film that dedicates to compensate the stress, in addition to the passivation film that may also perform as the additional stress-compensation film, wherein the stress-compensation multi-layered structure is provided. It is also possible that the stress-compensation film that dedicates to compensate the stress, in addition to each of the oxide film and the passivation film that may also perform as the additional stress-compensation film, wherein the stress-compensation multi-layered structure is provided. The stress-compensation multi-layered structure is more advantageous than the stress-compensation single-layered structure for the following reasons. The stress-compensation multi-layered structure may cause that the stress to bend the substrate 1 is dispersed into the stress-compensation film that dedicates to compensate the stress and into each of the oxide film and the passivation film that may also perform as the additional stress-compensation film. The compressive stress of the stress-compensation multi-layered structure compensates the stress that works to bend the substrate 1.

The stress-compensation single-layered structure has a compressive stress that compensates the stress that works to bend the substrate 1. The stress-compensation multi-layered structure also has a compressive stress that compensates the stress that works to bend the substrate 1. A typical example of the stress that works to bend the substrate 1 may be, but is not limited to, a tensile stress. The stress-compensation multi-layered structure includes at least first and second stress-compensation films, wherein the second stress-compensation film is closer to the semiconductor device structure than the first stress-compensation film. The semiconductor device structure may include the uppermost-level interconnection layer 2c. The first and second stress-compensation films have first and second compressive stresses. The compressive stress possessed by the stress-compensation structure may be applied to the semiconductor device structure that may include the uppermost-level interconnection layer 2c. Application of the strong compressive stress to the uppermost-level interconnection layer 2c may cause that the uppermost-level interconnection layer 2c is peeled or disconnected. It is effective to reduce the compressive stress that is applied to the uppermost-level interconnection layer 2c, in order to avoid the uppermost-level interconnection layer 2c from being peeled or disconnected due to the application of the strong compressive stress. In order to reduce the compressive stress that is applied to the uppermost-level interconnection layer 2c, it might be effective that the first compressive stress is greater than the second compressive stress because the second stress-compensation film is closer to the uppermost-level interconnection layer 2c than the first stress-compensation film. In order to reduce the compressive stress that is applied to the uppermost-level interconnection layer 2c, it might be effective that the closest stress-compensation film that is closer to the semiconductor device structure than any other stress-compensation film has a smallest compressive stress. If the oxide film performs as the additional stress-compensation film, it is preferable that the compressive stress possessed by the oxide film 3 is smaller than the compressive stress possessed by the stress-compensation film 6.

If the oxide layer 3 and/or the passivation layer 4 functions as the stress-compensation film 6, it may be assumed to have a stress compensation layer with a multi-layered structure. When the stress-compensation film 6 has the multi-layered structure, the stress caused by providing the stress-compensation film 6 is dispersed, compared with the case where the stress-compensation film 6 has one layer. Accordingly, the influence of the stress, which is caused by providing the stress-compensation film 6, applied to the interconnection layer 2 of the uppermost layer can be reduced, and the amount of stress of the stress-compensation film 6 can be accurately controlled to become the amount corresponding to the stress which occurs due to the grinding of the substrate 1 from the back surface side and bends the substrate 1. As a result, the bending of the substrate 1 occurring when the substrate 1 is ground from the back surface side can be prevented more effectively.

In addition, it is preferable that the stress-compensation film 6 include an oxide layer. Specifically, it is preferable that the stress-compensation film 6 include one or two or more oxide layers selected from a TEOS (tetraethoxysilane) oxide layer, an SiH₄ oxide layer, an HDP (high-density plasma) oxide layer, and an SiO₂ layer. In addition, it is preferable that the stress-compensation film 6 be a layer formed by the plasma CVD method. In particular, it is preferable that the stress-compensation film 6 include one or two or more oxide layers selected from a TEOS oxide layer, an SiH₄ oxide layer, an HDP oxide layer, and an SiO₂ layer formed by the plasma CVD method.

As the oxide layer 3, for example, a layer which is configured to include an SiO₂ layer or the like and which is formed by the plasma CVD method is preferable, even though it is not particularly limited.

In addition, it is preferable that the thickness of the oxide layer 3 be 80 nm or less, and it is more preferable that the thickness of the oxide layer 3 be 50 nm or less.

In addition, similar to the stress-compensation film 6, the oxide layer 3 may have stress (for example, compressive stress) which compensates the stress (for example, tensile stress) which occurs due to the grinding of the substrate 1 from the back surface side and bends the substrate 1. This is preferable because the oxide layer 3 can function as a layer, which forms a stress compensation layer, together with the stress-compensation film 6. In the present embodiment, the oxide layer 3 can be made to function as the stress compensation layer by setting the stress of the oxide layer 3 to be negative (−). Accordingly, it is preferable that the stress of the oxide layer 3 be set to about −100 Mpa. If the oxide film performs as the additional stress-compensation film, it is preferable that the compressive stress possessed by the oxide film 3 is smaller than the compressive stress possessed by the stress-compensation film 6. By setting the stress of the oxide layer 3 smaller than that of the stress compensation layer, the influence of the large stress of the stress compensation layer applied to the interconnection layer 2 of the uppermost layer can be reduced. As a result, peeling or disconnection of the interconnection layer 2 of the uppermost layer can be prevented.

As the passivation layer 4, a layer which is configured to include an SiON layer or an SiN layer, for example, and which is formed by the plasma CVD method is preferable, even though it is not particularly limited. Similar to the stress-compensation film 6, when the passivation layer 4 includes the SiON layer formed by the plasma CVD method and/or the SiN layer formed by the plasma CVD method, the passivation layer 4 may have stress (for example, compressive stress) which compensates the stress (for example, tensile stress) which occurs due to the grinding of the substrate 1 from the back surface side and bends the substrate 1. This is preferable because the passivation layer 4 can function as a layer, which forms a stress compensation layer, together with the stress-compensation film 6. In the present embodiment, the oxide layer 3 can be made to function as a stress compensation layer by setting the stress of the passivation layer 4 to be negative (−).

As the substrate 1, for example, a silicon substrate may be used, even though it is not particularly limited.

As the interconnection layer 2, it is preferable to use a interconnection layer containing Al, even though it is not particularly limited.

As the protective layer 5, for example, a polyimide layer with a thickness of 4 to 9 μm may be used, even though it is not particularly limited.

In order to manufacture the semiconductor device shown in FIGS. 1A and 1B, a semiconductor device structure including components necessary for the semiconductor device, such as a transistor (not shown), a capacitor (not shown), and a plurality of interconnection layers (not shown except for a interconnection layer of the uppermost layer), and the stress-compensation film 6 is formed on the top surface of the substrate 1.

More specifically, as shown in FIG. 3A, the lower inter-layer insulator 9 is formed over the top surface of the substrate 1. A Cu-stopper film 10 is formed over the lower inter-layer insulator 9. The low dielectric film 11 is formed over the Cu-stopper film 10. The first-level interconnection layers 2a of Cu is formed which extends over the Cu-stopper film 10. The first-level interconnection layers 2a of Cu are formed so that the first-level interconnection layers 2a of Cu are embedded in the low dielectric film 11. The cap layer 12 is formed over the low dielectric film 11. The Cu-stopper film 13 is formed over the first-level interconnection layers 2a of Cu and over the cap layer 12. The low dielectric film 14 is formed over the Cu-stopper film 13. The second-level interconnection layer 2b of Cu is formed in the low dielectric film 14. The second-level interconnection layer 2b of Cu is formed so that the second-level interconnection layer 2b of Cu is electrically connected through a contact plug to the first-level interconnection layers 2a of Cu. The cap layer 15 is formed over the low dielectric film 14. The Cu-stopper film 16 is formed over the second-level interconnection layer 2b of Cu and the low dielectric film 14. The upper inter-layer insulator 17 is formed over the Cu-stopper film 16. The bonding pad 7 is formed over the upper inter-layer insulator 17. The third-level interconnection layer 2c of Al is formed so that the third-level interconnection layer 2c of Al extends over the upper inter-layer insulator 17. The third-level interconnection layer 2c of Al is formed so that the third-level interconnection layer 2c of Al electrically connected through a contact plug to the second-level interconnection layer 2b of Cu. The third-level interconnection layer 2c of Al performs as the uppermost-level interconnection layer 2c.

Then, as shown in FIG. 3B, the oxide layer 3 and the stress-compensation film 6 are formed on the interconnection layer 2 of the uppermost layer sequentially from below. Then, as shown in FIG. 1B, the passivation layer 4 and the protective layer 5 are formed on the stress-compensation film 6 sequentially from below.

It is preferable that the oxide layer 3, the stress-compensation film 6, and the passivation layer 4 can be formed by the plasma CVD method. When the oxide layer 3, the stress-compensation film 6, and the passivation layer 4 are formed by the plasma CVD method, the amount of stress of these layers can be arbitrarily controlled by adjusting the high-frequency bias condition and the low-frequency bias condition in the plasma CVD method. In the present invention, it is preferable that the oxide layer 3 and the passivation layer 4 be formed to have negative stress and the stress-compensation film 6 be formed such that the stress is in a range of −200 MPa to −350 MPa by the plasma CVD method.

In addition, the protective layer 5 is formed by a method of applying polyimide, for example. The bonding pad opening 8 is formed in the oxide layer 3, the stress-compensation film 6, the passivation layer 4, and the protective layer 5 so that the bonding pad opening 8 is positioned over the bonding pad 7.

After forming the semiconductor device structure on the top surface of the substrate 1 as described above, the semiconductor device is made thin by polishing or grinding the substrate 1 from the back surface side, thereby obtaining the semiconductor device shown in FIGS. 1A and 1B. The semiconductor device shown in FIGS. 1A and 1B obtained as described above is then diced and packaged with high integration.

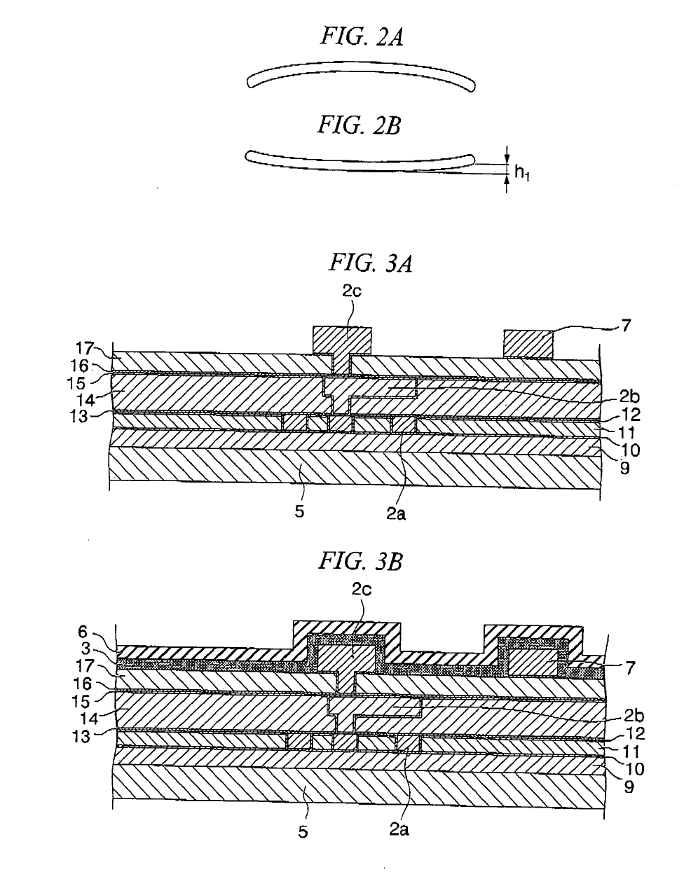

The bending of the semiconductor device shown in FIGS. 1A and 1B will be described with reference to FIGS. 2A and 2B. FIG. 2A is a schematic cross-sectional view explaining the state of the bending in the phase where the forming of the semiconductor device structure on the top surface of the substrate is finished in the manufacturing process of the semiconductor device shown in FIGS. 1A and 1B, and FIG. 2B is a schematic cross-sectional view explaining the state of the bending of the semiconductor device after the grinding of the substrate.

In the manufacturing process of the semiconductor device shown in FIGS. 1A and 1B, the semiconductor device bends in the protruding shape with the top surface side of the substrate 1 upward in the phase where the forming of the semiconductor device structure on the top surface of the substrate 1 is finished, as shown in FIG. 2A. When the stress-compensation film 6 is not provided, the semiconductor device shown in FIGS. 1A and 1B bends in the recessed shape with the top surface side of the substrate 1 upward due to the grinding of the substrate 1 from the back surface side. Accordingly, in the phase before the grinding of the substrate 1 from the back surface side, the bending in the opposite direction is caused by stress (for example, compressive stress) of the stress-compensation film 6

Moreover, in the semiconductor device after grinding the substrate 1, the top surface side of the substrate 1 is contracted by stress (for example, tensile stress) which occurs due to the grinding of the substrate 1 from the back surface side and bends the substrate 1. Accordingly, since stress (for example, compressive stress) of the stress-compensation film 6 is offset, after the grinding of the substrate 1, the semiconductor device slightly bends in the recessed shape with the top surface side of the substrate 1 upward so that it can be easily diced, as shown in FIGS. 1A and 2B.

The semiconductor device of the present embodiment includes: the semiconductor device structure formed on the top surface of the substrate 1; and the stress-compensation film 6 which is formed within the semiconductor device structure and which compensates the stress which occurs due to the grinding of the substrate 1 from the back surface side and bends the substrate 1. Accordingly, stress (for example, tensile stress) which occurs due to the grinding of the substrate 1 from the back surface side and bends the substrate 1 is offset or compensated by stress (for example, compressive stress) of the stress-compensation film 6. Thus, according to the present embodiment, the bending of the substrate occurring when the substrate 1 is ground or polished from the back surface side can be prevented. As a result, since dicing can be easily performed, a semiconductor device that can be packaged with high integration can be realized.

Moreover, in the semiconductor device of the present embodiment, when the stress-compensation film 6 is made to have a thickness of 1.0 μm to 2.0 μm, an effect of offsetting the stress that bends the substrate 1 by the stress-compensation film 6 is sufficiently achieved, and it becomes a thin semiconductor device with an appropriate thickness as a semiconductor device packaged with high integration.

In addition, in the semiconductor device of the present embodiment, the semiconductor device structure includes a plurality of interconnection layers, the passivation layer 4 and the protective layer 5 provided on the passivation layer 4 are disposed on the interconnection layer 2 of the uppermost layer among a plurality of interconnection layers, and the stress-compensation film 6 is disposed between the interconnection layer 2 of the uppermost layer and the passivation layer 4. Accordingly, there is no possibility that the stress applied to the semiconductor device by the stress-compensation film 6 will cause trouble in each process of forming a transistor or a capacitor, which is performed until the process of forming the stress-compensation film 6, which is preferable.

In addition, the manufacturing method of the semiconductor device of the present embodiment includes a process of forming the semiconductor device structure on the top surface of the substrate 1 and a process of grinding the substrate 1 from the back surface side, and the process of forming the semiconductor device structure includes a process of forming the stress-compensation film 6 which compensates the stress which occurs due to the grinding of the substrate 1 from the back surface side and bends the substrate. Accordingly, the stress which occurs due to the grinding of the substrate 1 from the back surface side and bends the substrate can be offset by the stress of the stress-compensation film 6. Thus, according to the manufacturing method of the present embodiment, the bending of the substrate 1 occurring when the semiconductor device is made thin by grinding the substrate 1 from the back surface side is unlikely to occur after forming the semiconductor device structure on the top surface of the substrate 1. As a result, it is possible to easily manufacture a thin semiconductor device that can be easily diced.

Moreover, in the present embodiment, the case where the semiconductor device bends in the recessed shape with the top surface side of the substrate 1 upward when the stress-compensation film 6 is not provided has been mentioned as an example. However, by appropriately changing the stress of the stress compensation layer, the invention may also be applied to the case where the semiconductor device bends in the protruding shape with the top surface side of the substrate upward when the stress-compensation film 6 is not provided.

### EXAMPLES

Hereinafter, the invention will be specifically described through an example and a comparative example.

### Example 1

The semiconductor device shown in FIGS. 1A and 1B, which is an example of the invention, was obtained by the following manufacturing method. First, the substrate 1 formed of a silicon substrate with a diameter of 300 mm and a thickness of 750 μm was prepared, and the semiconductor device structure including components necessary for the semiconductor device, such as a transistor, a capacitor, and a plurality of interconnection layers, and the stress-compensation film 6 was formed on the top surface of the substrate 1.

In addition, an Al interconnection layer with a thickness of 1.1 μm was formed as the interconnection layer 2 of the uppermost layer among a plurality of interconnection layers included in the semiconductor device structure. On the interconnection layer 2 of the uppermost layer, an SiO₂ layer which functions as a stress compensation layer and has a thickness of 80 nm and stress of −100 MPa was formed as the oxide layer 3 by the plasma CVD method in which the layer forming conditions, such as power of low frequency bias, were adjusted. In addition, a TEOS oxide layer with a thickness of 1.5 μm and stress of −250 MPa was formed as the stress-compensation film 6 on the oxide layer 3 by the plasma CVD method in which the high-frequency bias was 250 W and the low frequency bias was 870 W. On the stress-compensation film 6, an SiN layer with a thickness of 500 nm was formed as the passivation layer 4 by the plasma CVD method. Then, the protective layer 5 was formed by applying polyimide on the passivation layer 4.

Here, the bending of the semiconductor device of the first example in the phase where forming the semiconductor device structure on the top surface of the substrate 1 was finished was checked. As a result, the bending of the semiconductor device of the first example was 200 μm in the protruding shape with the top surface side of the substrate 1 upward.

Then, the semiconductor device was made thin by grinding the substrate 1, which had the semiconductor device structure formed on the top surface, from the back surface side until the thickness of the substrate 1 reached 50 μm.

In addition, the bending (the amount of bending is expressed by reference numeral “h₁” in FIG. 2B) of the semiconductor device of the first example obtained after grinding the substrate 1 was checked. As a result, the bending of the semiconductor device of the first example was about 1 cm in the recessed shape with the top surface side of the substrate 1 upward. In addition, the semiconductor device of the first example could be diced easily.

### Comparative Example 1

The known semiconductor device shown in FIGS. 4A and 4B was obtained by the following manufacturing method.

That is, the semiconductor device of the first comparative example was obtained in the same manner as in the first example except that the stress-compensation film 6 was not provided.

In addition, in the first comparative example, there was no bending of the semiconductor device in the phase where the forming of the semiconductor device structure on the top surface of the substrate 1 was finished.

However, in the semiconductor device of the first comparative example obtained after grinding the substrate 1, bending (the amount of bending is expressed by reference numeral “h₂” in FIG. 5B) of 4 cm to 5 cm occurred in the recessed shape with the top surface side of the substrate 1 upward. In addition, in the semiconductor device of the first comparative example, dicing could not be performed since the bending was large.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a substrate;
a semiconductor device structure over the substrate, the semiconductor device structure including an uppermost level interconnection layer;
an insulating film that covers the uppermost level interconnection layer; and
a stress-compensation film having a first stress that compensates a second stress, the second stress working to bend the substrate, the second stress being generated by polishing the bottom surface of the substrate, the first stress of the stress-compensation film being greater than a third stress of the insulating film.

2. The semiconductor device according to claim 1, wherein the insulating film is interposed between the stress-compensation film and the uppermost level interconnection layer.

3. The semiconductor device according to claim 1, wherein the insulating film comprises an oxide film.

4. The semiconductor device according to claim 1, wherein the first and third stresses are compressive stresses and the second stress is a tensile stress.

5. The semiconductor device according to claim 1, wherein the first stress of the stress-compensation film is in the range of −200 MPs to −350 MPs.

6. The semiconductor device according to claim 1, wherein the stress-compensation film has a thickness in the range of 1.0 μm to 2.0 μm.

7. The semiconductor device according to claim 1, wherein the insulating film having the third stress performs as an additional stress-compensation film.

8. The semiconductor device according to claim 1, further comprising:
a passivation film over the stress-compensation film; and
a protective film over the passivation film.

9. The semiconductor device according to claim 1, further comprising:
a passivation film over the insulating film and under the stress-compensation film; and
a protective film over the stress-compensation film.

10. A semiconductor device comprising:
a substrate;
a semiconductor device structure over the substrate;
an insulating film that covers the semiconductor device structure; and
a stress-compensation film over the insulating film, the stress-compensation film having a first stress that compensates a second stress, the second stress working to bend the substrate.

11. The semiconductor device according to claim 10, wherein the second stress is a stress generated by polishing the bottom surface of the substrate.

12. The semiconductor device according to claim 10, wherein the insulating film has a third stress, and the insulating film having the third stress performs as an additional stress-compensation film,
the first and third stresses are compressive stresses and the second stress is a tensile stress, and
the first stress of the stress-compensation film is greater than the second compressive stress of the insulating film.

13. The semiconductor device according to claim 10, wherein the first stress of the stress-compensation film is in the range of −200 MPs to −350 MPs.

14. The semiconductor device according to claim 10, wherein the stress-compensation film has a thickness in the range of 1.0 μm to 2.0 μm.

15. The semiconductor device according to claim 10, wherein the insulating film comprises an oxide film, and the semiconductor device structure includes an uppermost level interconnection layer which is covered by the insulating film.

16. The semiconductor device according to claim 10, further comprising:
a passivation film over the stress-compensation film; and
a protective film over the passivation film.

17. The semiconductor device according to claim 10, further comprising:
a passivation film over the insulating film and under the stress-compensation a protective film over the stress-compensation film.

18. A method of forming a semiconductor device, the method comprising:
forming a semiconductor device structure over the top surface of a substrate;
forming a stress-compensation film over the semiconductor device structure, the stress-compensation film having a first stress; and
polishing the bottom surface of the substrate with generating a second stress on the substrate, the second stress working to bend the substrate, the second stress being compensated by the stress-compensation film with the first stress.

19. The method according to claim 18, wherein the first stress of the stress-compensation film is in the range of −200 MPs to −350 MPs.

20. The method according to claim 18, wherein the stress-compensation film is formed by a plasma chemical vapor deposition.
